(19) United States
(12) Patent Application Publication
(10) Pub. No.: US 2008/0266797 A1
(43) Pub. Date: Oct. 30, 2008

(54) Surface airflow heatsink device and the heatsink device components

(75) Inventor: I-Shih Tseng, Taoyuan Hsien (TW)

Correspondence Address: WANG, HARTMANN & GIBBS, 1301 DOVE STREET, SUITE 1050, NEWPORT BEACH, CA, 92660, US

(73) Assignee: Chroma Ate. Inc., Taoyuan Hsien (TW)

(21) Appl. No.: 11/982,658

(22) Filed: Nov. 1, 2007

(30) Foreign Application Priority Data
Nov. 3, 2006 (TW) 095140850

(51) Int. Cl. H05K 7/20

(52) U.S. Cl. 361/697

(57) ABSTRACT

It's a type of top mount surface airflow heatsink, utilizing the upper ceiling wall separated by an air gap, working together with the upper surface of a heating device (microprocessor) producing an air current. It's a simple device, with a low cost using the Reynolds Equation Re=(ρuₘd)/μ≧2,500; with ρ being the fluid density, uₘ being the free-stream fluid velocity, d being the pipe distance or diameter, μ being the fluid viscosity. Since the airflow produces air turbulence, it causes the frequent heat exchanges in the air. It also causes the obvious temperature changes within the different layers of air. Therefore, it increases tremendously, the efficiency of dissipating the heat. It requires only the input of the air. The operation is simple and it allows the usage of even higher heat generating devices. Thus it promotes the alternative usage of this top mount heatsink device within the installation of circuit board components.

### FIELD OF THE INVENTION

This invention is a heatsink device, specifically, a surface airflow heatsink device.

### BACKGROUND OF THE INVENTION

With the increase advance and popularity of the semiconductor, the semiconductor circuit by itself is getting more complex and it requires more energy therefore, producing more heat. On the other hand, once the operating temperature reaches over 120 degrees Celsius, not only the silicon chips may be damaged, even the semiconductor components and the circuit board may melt under the extreme high temperature which may disrupt electrical conduct. Therefore, creating the problems of short-circuit.

Therefore, whether it's the mother-board, video card, or any other semi-conductor board, as shown in FIG. 1, on top of the semiconductor unit (10), it's applied a coating of heat conductor gel (14) to hold the heatsink fins (16) and the semiconductor chip together. If this is not good enough, a cooling fan (18) can be added on top of the heatsink, so the heat produced by the circuit board (12) and the semiconductor chip (10) can be dissipated through the heatsink fins (16). Therefore reducing the heat accumulation and preventing the damage to the semiconductor chip (10).

Furthermore, as shown in FIG. 2, a U.S. Pat. No. 6,603,658, this invention has an air duct (26), to direct the airflow from the fan (28), to provide a stable air current flowing toward the circuit board (22) and over the heat device, microprocessor (20). So the heat produced by the heat device, microprocessor (20) can be dissipated. As an example, it can reduce the internal temperature of a notebook device.

The air duct (26) as shown on FIG. 3, it's not directly attached to the heat device (20). The distance between the air duct (26) and heat device (20) is many times longer than the measurement of the opening width. Therefore, the airflow (280) from the air duct (26) with the laminar jet airflow will steadily move across the surface of the semiconductor unit (20), even creating a stagnation region between the surface of the semiconductor unit (20) and the contact area of the airflow, initiating a heat exchange. To maintain a stable laminar jet airflow, the previous patent using the Reynolds Equation Re=(ρuₘd)/μ≧2,500; with ρ being the fluid density, uₘ being the free-stream fluid velocity, d being the pipe distance or diameter, μ being the fluid viscosity.

Although, in relation to the high volume heat produced by the computer and electronic equipments, using the above mentioned laminar jet airflow method by itself, it'll not yield a satisfactory result. Especially, when using high complexity circuit components, and with the increased amounts of the electronic components being used in the circuit boards, it'll only increase the heat generated on specific isolated areas. The ability to effectively, disperse the heat produced by the electronic components will be the key to increase the overall performance.

Therefore, many electronic equipments rely on water since they have the ability to absorb higher capacity of heat and therefore, removing a large quantity of heat. But to insert water tracks within the circuitry, it involves the filling of the water as well as the complete drainage. It must work within a confined space. It must take every precaution in preventing any water backflow, which will cause short-circuits. It affects the overall safety. It shows that this case involves a certain degree of danger.

On the other hand, there is another much safer method. It involves the filling of liquid nitrogen or cool air. Because of the great differences in the air temperatures, it'll reduce great amount of heat. But, this method is not only very costly, but also it must first drain the liquid condensation, to prevent the accumulation of the humidity, which may drip into the circuit components.

If there's an option of not having to cool the filling air and still be able to increase the performance of the heat dissipation, it'll not only guarantee the smooth circuit operation, preventing the unnecessary problems of higher energy consumption and humidity accumulation. It'll give more flexibility and options to choose the circuit components. To maximize the efficiency and performance of the electronic components is a subject worthy of studying.

### SUMMARY OF THE INVENTION

Therefore, one of the purposes of this invention is to provide a heatsink device that can maximize the efficiently of cooling the temperature.

Another purpose of this invention is to provide a heatsink device with a simple mechanism that is easy to operate. Another purpose is to provide a low cost heatsink device that has the flexibility of choosing circuit components that can greatly reduce the heat.

Therefore, this invention, the surface airflow heatsink device can cover one heat device with a constant air feed supply. It receives the air feeds from an air compressing unit. Directing outward the heat generated by the heat device. The heatsink device includes the following: a ceiling wall, a heating unit attachment, which the size of the heating unit and the heat conducting wall should be the same. In between the ceiling wall and the heat conducting wall, an air gap separates them. The air current system is originated from the Reynolds Equation Re=(ρuₘd)/μ≧2,500; with ρ being the fluid density, uₘ being the free-stream fluid velocity, d being the pipe distance or diameter, μ being the fluid viscosity.

This invention utilizes great volumes of air supply, forcing it to produce air turbulence, increasing the airflow between layers of air. It stabilizes the temperature in a short amount of time. Not only it is a simple device, the manufacturing cost is also very low, and there is no need to induce cooling agent to operate. There's no need to reduce the air humidity, therefore, preventing it from the dangers of an accidental leakage. It has an easy operation, built on a simple mechanism. At the same time, it fulfills the function of the heat reduction, avoiding unnecessary higher energy consumption, and it increases the use of the circuit components. It also increases the dependability and the stability of the electronic circuits. It solves all the previous problems and accomplishes the goals of this patent case.

### BRIEF DESCRIPTION OF THE DRAWINGS

The invention is generally shown by way of reference to the accompanying drawings:

FIG. 1, a traditional heatsink device and microprocessor component of a circuit board;

FIG. 2, U.S. Pat. No. 6,603,658 patent invention of a heatsink operational diagram;

FIG. 3, the airflow diagram produced by the heatsink from FIG. 2;

FIG. 4, the best case scenario 3-D diagram of the top mounted heatsink of this invention;

FIG. 5, display diagram of FIG. 4, with examples of air current flowing inside the air chamber;

FIG. 6A, display diagram of FIG. 5, with different layers of air flowing inside the air chamber and the distribution of the air heat;

FIG. 6B, display diagram of FIG. 6A, the distribution of air temperature;

FIG. 7, the second best case scenario, example of structure schematic drawing implementation; and

FIG. 8, the third best case scenario, example of structure schematic drawing implementation.

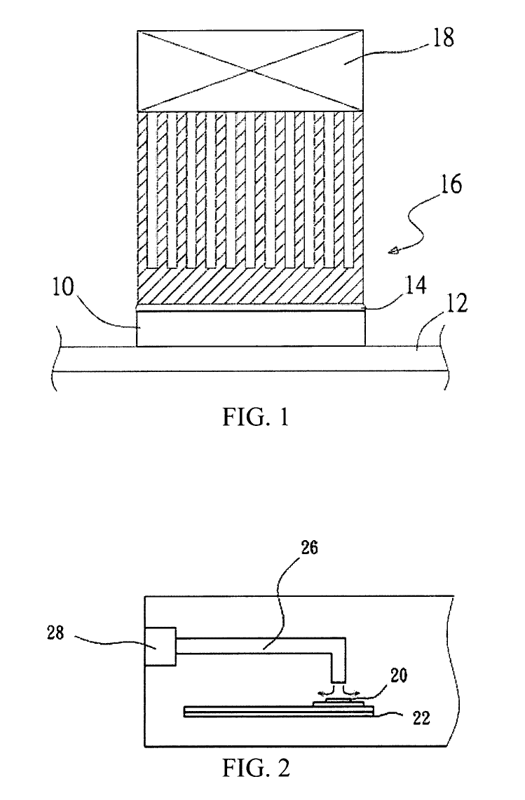

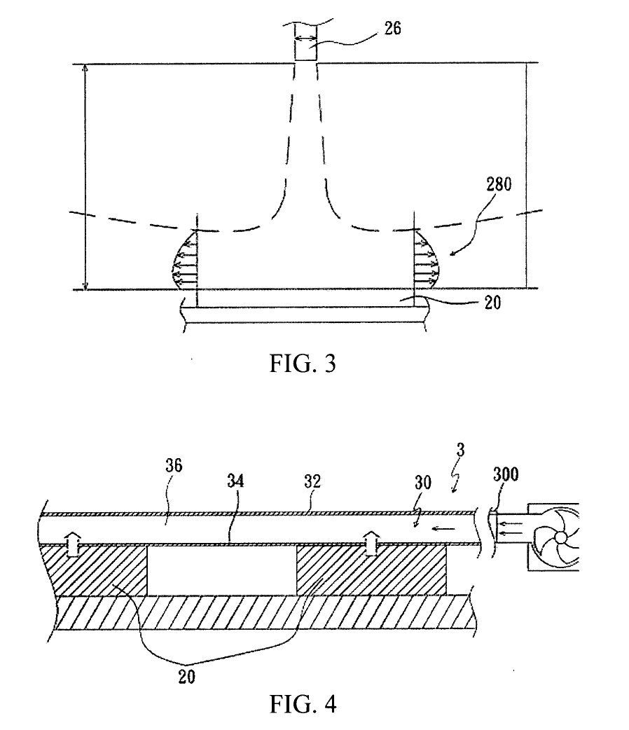

### DETAILED DESCRIPTION OF THE INVENTION

Regarding this invention and the previously mentioned technology, it will all be described in detail in the following diagrams.

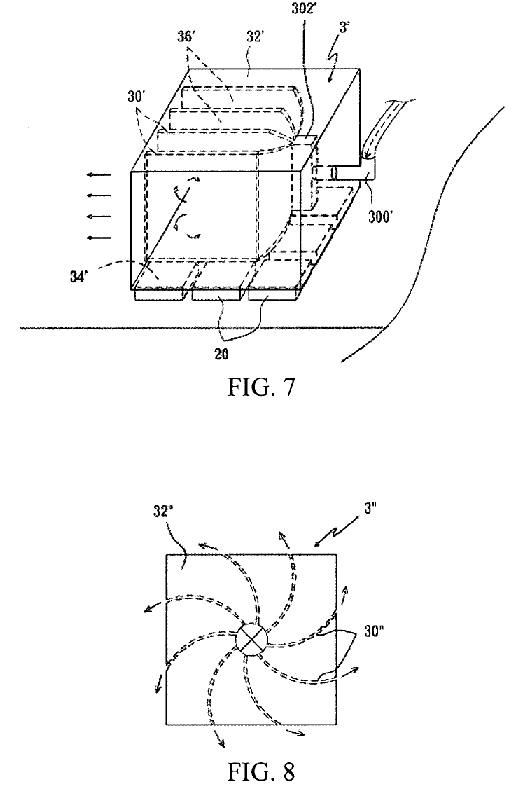

Regarding FIG. 7, a simple description of each component follows:

| Component | Description |
|---|---|
| 3′ | Heatsink Device |
| 20 | Transistor Unit |
| 30′ | Air Track |
| 34′ | Heat Conducting Wall |
| 300′ | Connecting Point |
| 302′ | Storage Chamber |

Regarding all Figures, a description of the main components follows:

| Component | Description |
|---|---|
| 3, 3′, 3″ | heatsink device |
| 4 | air supply unit |
| 10, 20 | semiconductor unit |
| 12, 22 | circuit board |
| 14 | heat conducting gel |
| 16 | heatsink fins |
| 18, 28 | fan |
| 26 | air pipe |
| 30, 30′, 30″ | air duct |
| 32, 32′, 32″ | ceiling wall |
| 34, 34′ | heat conducting wall |
| 36, 36′ | separation wall |
| 280 | air current |
| 300, 300′ | connecting point |
| 302 | lowest layer |
| 304, 306 | layer above |
| 308 | top layer |
| 302′ | storage chamber |
| 380 | uniform |
| 381 | elliptical curve |
| 382 | air turbulence |
| 804 | buckles |
| 902 | fixed hole |
| 904 | side extensions with holes |
| 906 | screws |

The first implementation of the surface airflow heatsink device (3) as illustrated in FIG. 4, has a ceiling wall (32), a heat conducting wall (34). Between the ceiling wall (32) and the heat conducting wall (34) is the separation chamber (36). The heat conducting wall (34) is made of heat conducting material. It also has the matching size with the heating device (20), which makes them tightly attached. The ceiling wall (32), the heat conducting wall (34) and the separation chamber (36) together devise an air track (30). The air track (30) has a connecting point (300) all connecting to an air supply system (4) a fan. The height between the separation chamber (36) connecting to the ceiling wall (32) is shorter than the distance of the heat conducting wall (34).

The air coming from the fan (4) will enter through the connecting point (300) and continue through the air duct (30). The air duct (30) has a specific measurement of cross-section. It makes the airflows through the air duct (30) and is derived from the Reynolds Equation Re=(ρuₘd)/μ≧2,500; with ρ being the fluid density, uₘ being the free-stream fluid velocity, d being the pipe distance or diameter, μ being the fluid viscosity. Therefore, the heat produced by the heat device (20), is transferred through the tight attachment between the heating unit (20) and the heat conducting wall (34) to the heatsink device (3). The heat exchange between the air current and the heat conducting wall (34) will expel the heat produced by the heating unit (20).

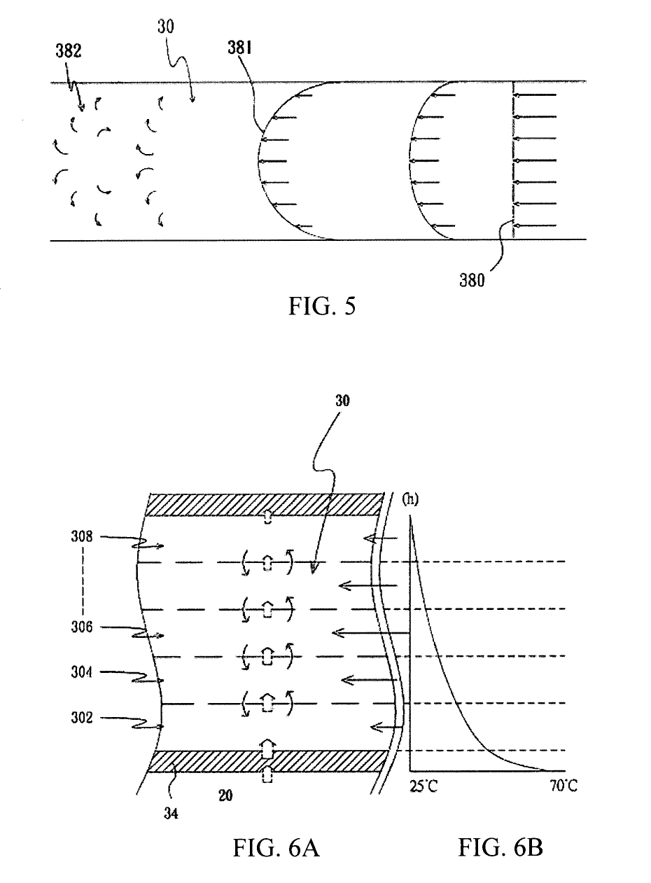

As illustrated on FIG. 5, a typical air current has a constant speed flowing into a channel. At first, the flowing speed will be as shown on the right of the diagram, with an uniform advancement (380). Later on, because of the friction between the air channel (30) and the flowing air, also because of the air viscosity effect, as the air current approaches the air channel (30), it makes the air flowing closer to the wall surface to slowdown, even stopping it altogether. Contrarily, the air flowing in the center of the air channel (30) do not get affected; which eventually will form an elliptical curve (381) as shown. On the other hand, if the flowing speed is too fast, or if the viscosity is low, it will make each air particle flow on different directions. It'll make different layers interact with one another, producing air turbulence (382).

Further consideration for the internal and external temperatures of the air channel, as illustrated in FIG. 6A; when heat device (20) located below the air channel (30), utilizing the heat conduction of the heat conducting wall (34), it will carry the heat produced by the heat device (20) toward the air channel (30). It'll force the room temperature air pass through the air channel (30), moving from right to left. If the air inside the air channel (30), remain in good flowing manner as shown in dashed line, the lowest layer of air (302) in the air channel (30) will initiate a heat exchange. The lowest layer of air (302) will slowly absorb the heat and rise. The heat exchange rate will slow down. The lowest layer of air (302) will interact less with the upper layers (304) and (306), it'll make the heat exchange less frequent. It'll make the most upper layer of air (308) remain in room temperature, but it does not help the increasing temperature from the lowest layer of air (302).

Inversely, if the air current becomes turbulent then the layers of air will become very active. The lowest layer of air (302) will absorb part of the heat coming from the heat conducting wall (34). It'll then move upward to the upper layers (304), (306). The room temperature air, of the layers (304) and (306) will move downward. Therefore, maintaining a difference in temperatures between the air from lowest layer (302) and the heat conducting wall (34). It increases the heat exchange. As illustrated by the FIG. 6B, when the temperature of the inflow air reaches 25 degrees Celsius, the temperature of the heat conducting wall (34) can remain in the 70 degrees Celsius. Which makes the air inside air channel (30) absorb the heats from upper layers (308), (306), (304) to the lowest layer (302) and moving them altogether.

To prove the above theory, the inventor used two 40 watts (each) resistors to simulate the heat device. Without a heatsink, temperature of the resistors can reach to 170 degrees Celsius. As mentioned previously, if comparing instead, with semi-conductor devices, under the same heat condition, they'll already be burned out. On the other hand, without using induction of air, instead, using the top mount heatsink from this patent alone, as heat conducting unit, the temperature of the operating resistors can reach up to 110 degrees Celsius. But using induction of compressed air as this patent intends, the temperature of the resistors have decreased to 70 degrees Celsius. The current single chip electronic component does not use more than 4 or 5 watts. Using the prototype of this patent's top mount heatsink, can easily safeguard at least 20 circuit components. It'll allow a smooth operation under a safe environment.

Especially, separating the air flowing from upward to downward, the difference in temperatures between the upward heat device and the downward heat device is less than 2 degrees Celsius. It insinuates that the air inside the cooling device is able to remove the heat, preventing the heat accumulation. Besides, the induced air is of the room temperature. Not only it does not have the humidity problem, it can really remove the heat out of the heatsink. It'll let the heating air inside the electronic components to disperse without having to worry about the installation safety issues of the cooling fluid devices.

On the other hand, there are different heat conducting materials that may differ slightly by the thermal resistance, like copper and aluminum. If they are used on the same experiment, you'll discover that the effect of the reduced temperature is not much different. In other words, the top mount heatsink presented in this case, can lead to low cost and the easy manufacturing of the metals, but it does not need to be restricted by the quality of the materials.

Certainly, the technician who is familiar with the technology can easily understand. The preceding implementation which, shape the form of the air duct is not important. As illustrated in FIG. 7, the second best case scenario, the heatsink device (3′) can spread the air to the almost vertical attachment to the heat device (20) and the heat conducting wall (34′) toward the direction of the air duct (30′). As it limits the narrow opening of the air duct (30′), both affecting the formation of the air separation chamber (36′) connecting to the ceiling wall (32′) and the heat conducting wall (34′), the height distance is further than the distance in between them. It makes the air supply enter through the connecting point (300′) and into the air storage chamber (302′). Inside the air duct (3′) as long as the Reynolds number remains above 2500, the air current becomes the air turbulence then, it'll achieve the same result.

As illustrated in FIG. 8, the input air through the use of the heatsink device (3″) the ceiling wall (32″), will disperse through the air duct (30″) of the heatsink device forming an elliptical shape in the center, dispersing the air and achieving the heat dissipation required.

This case uses the air turbulence formed inside the air chamber, guaranteeing a massive intermolecular heat exchange, causing the lowest layer of air elevate due to differences in air temperature. By using the air cooling effect it increases the performance efficiency. The device is so simple that there's no need to worry about a short circuit. The production cost is low. Especially, when after the heat dissipation performance is increased, the circuit designers have the freedom to choose higher performance circuit components. They don't have to worry about the over heating problem which may lead to unstable circuit boards. The purpose of this patent device is to achieve the overall performance of the electronic circuit platforms

The above mentioned, are the best case scenarios for this invention. It cannot be limited to just these cases. Namely the overall information in this invention, the patent application, the scope and the invention instruction manual, even the slightest changes, all should still be covered by the scope of this invention patent.

What is claimed is:

1. A surface airflow heatsink device attached to a heat device. It uses the constant supply of airflow to dissipate the heat produced by the semiconductor chip. The heatsink device includes:
Ceiling wall;
Provide secure attachment to the heating unit and a heat conducting wall matching the size of the heating unit;
Ceiling wall extension, providing a surface gap between the ceiling wall and the semiconductor chip. The ceiling wall together with the semiconductor chip devises an airflow chamber. The airflow system is originated from an air supply unit and is derived from the Reynolds Equation Re=(ρuₘd)/μ≧2,500; with ρ being the fluid density, uₘ being the free-stream fluid velocity, d being the pipe distance or diameter, μ being the fluid viscosity.

2. The above described scope of claim 1, the surface airflow heatsink device, the heat conducting wall which include the wall itself and the side-surface walls of the air duct away from the heat conducting layers.

3. The above described scope of claim 1, the surface airflow heatsink device, the separation chamber installation system, the height distance connecting the ceiling wall and the heat conducting wall is much shorter than the distance between heat conducting wall and the separation chamber wall.

4. The above described scope of claim 1, the surface airflow heatsink device, the installation system of the separation chamber and the interaction with the separation walls, the height distance connecting the ceiling wall and the heat conducting wall is much larger than the distance between heat conducting wall and the separation chamber wall.

5. A type of heatsink component, which includes:
Heatsink device, which includes:
Ceiling wall;
A secure attachment to the heating unit, which has a heat conducting wall matching the size of the heating unit;
Between the ceiling wall and the heat conducting wall, together they devise an air separation chamber;
Connecting the air duct of the heatsink device, the air current derived from the Reynolds Equation Re=(ρuₘd)/μ≧2,500; with ρ being the fluid density, uₘ being the free-stream fluid velocity, d being the pipe distance or diameter, μ being the fluid viscosity.

6. Within the scope of claim 5 of the patent application, the description of the heatsink component, one of the air supply installation system, a fan.

7. A surface airflow heatsink device attached to a semiconductor chip which is a heat device, said heatsink using a constant supply of airflow to dissipate the heat produced by the semiconductor chip, said heatsink including:
a ceiling wall;
a secure attachment to the semiconductor chip and a heat conducting wall matching the size of the semiconductor chip; and
a ceiling wall extension providing a surface gap between the ceiling wall and the semiconductor chip;
wherein the ceiling wall together with the semiconductor chip devises an airflow chamber and the airflow system is originated from an air supply unit which is derived from the Reynolds Equation Re=(ρuₘd)/μ≧2,500, with ρ being the fluid density, uₘ being the free-stream fluid velocity, d being the pipe distance or diameter, and μ being the fluid viscosity.

8. A heatsink device adapted to be attached to a heat device, said heatsink using turbulent airflow to dissipate the heat produced by the heat device, said heatsink including:
a ceiling wall;
a heat conducting wall matching the size of the heat device and securely attached to the heat device;
a ceiling wall extension providing a surface gap between the ceiling wall and the heat device;
wherein the ceiling wall together with the heat device devises an airflow chamber and the airflow is originated from an air supply unit which is derived from the Reynolds Equation Re=(ρuₘd)/μ≧2,500, with ρ being the fluid density, uₘ being the free-stream fluid velocity, d being the pipe distance or diameter, and μ being the fluid viscosity.

9. The heatsink device of claim 8 wherein the heat device is a semiconductor chip.

10. The heatsink device of claim 8 wherein the airflow is constant.

11. The heatsink device of claim 8 wherein the airflow is controlled by a. pressure regulator.

12. The heatsink device of claim 8 for a heatsink device, including:
a heat conducting wall, which includes the wall itself and the side-surface walls of an air duct, which directs heat away from the heat conducting layers of the heat device.

13. The heatsink device of claim 8 for a heatsink device, including a separation chamber installation system having a height distance connecting the ceiling wall and the heat conducting wall which is much shorter than the distance between the heat conducting wall and the separation chamber wall.

14. The heatsink device of claim 8 for a heatsink device, including:
an installation system for a separation chamber and the interaction with the separation walls;
wherein the height distance connecting the ceiling wall and the heat conducting wall is much larger than the distance between the heat conducting wall and the separation chamber wall.

15. A heatsink component, which includes:
a heatsink device, which includes
a ceiling wall; and
a secure attachment to a heating unit which has a heat conducting wall matching the size of the heating unit,
the ceiling wall and the heat conducting wall together devising an air separation chamber;
wherein the air duct of the heatsink device is connected to said heatsink component, the air current derived from the Reynolds Equation Re=(ρuₘd)/μ≧2,500, with ρ being the fluid density, uₘ being the free-stream fluid velocity, d being the pipe distance or diameter, and μ being the fluid viscosity.

16. The heatsink component of claim 15, further including:
an air supply installation system; and
a fan.

17. A heatsink for a heat-producing device comprising:
a ceiling wall;
a heat conducting wall in contact with the heat-producing device; and
a ceiling wall extension providing a gap between the ceiling wall and the heat conducting wall;
wherein the ceiling wall and heat conducting wall form an airflow chamber which uses a turbulent supply of airflow to dissipate the heat produced by the heat device.

18. The heatsink device of claim 17 wherein the heat conducting wall is the same size as a surface of the heat-producing device.

19. The heatsink device of claim 17 wherein the heat-producing device is a microprocessor.

20. The heatsink device of claim 17 wherein the airflow originates from an air supply unit and the airflow is characterized by the Reynolds Equation Re=(ρuₘd)/μ≧2,500, with ρ being the fluid density, uₘ being the free-stream fluid velocity, d being the pipe distance or diameter, μ being the fluid viscosity.

21. The heatsink of claim 17 further comprising:
an air duct providing the turbulent supply of airflow, the air duct having a heat-conducting side-surface wall which conducts heat away from the heat device.

22. The heatsink of claim 17 further comprising:
a separation chamber disposed between the ceiling wall and the heat conducting wall, the separation chamber having a wall;
wherein the height of the separation chamber wall is less than the distance between the ceiling wall and the heat conducting wall.

23. The heatsink of claim 22 wherein the separation chamber has multiple parallel separation walls forming multiple air chambers.

24. The heatsink of claim 22 wherein the turbulent airflow causes air near the bottom of the separation chamber to move up and air near the top of the separation chamber to move down.

25. A heatsink component for a heat-producing device comprising:
a ceiling wall and a heat conducting wall, the heat conducting wall in contact with the heat-producing device;
an air separation chamber formed by the ceiling wall and the heat conducting wall; and
an air duct connected to the air separation chamber;
wherein the air current in the air duct is derived from the Reynolds Equation Re=(ρuₘd)/μ≧2,500, with ρ being the fluid density, uₘ being the free-stream fluid velocity, d being the pipe distance or diameter, and μ being the fluid viscosity.

26. The heatsink component of claim 25 wherein the size of the heat conducting wall matches the size of a surface of the heat-producing device.

27. The heatsink component of claim 25 further comprising:
an air supply installation system; and
a fan,
wherein the airflow from the air duct is directed by the fan to flow through the air separation chamber.
